(19) United States
(12) Patent Application Publication
(10) Pub. No.: US 2025/0147563 A1
(43) Pub. Date: May 8, 2025

(54) POWER CONVERSION DEVICE

(71) Applicant: Hitachi Industrial Equipment Systems Co., Ltd., Tokyo (JP)

(72) Inventors: Kazuaki TOBARI, Tokyo (JP); Yoshiyuki TAGUCHI, Tokyo (JP); Yuta IWASE, Tokyo (JP)

(21) Appl. No.: 18/751,703

(22) Filed: Jun. 24, 2024

(30) Foreign Application Priority Data
Nov. 8, 2023 (JP) 2023-190952

(51) Int. Cl. G06F 1/26; G01R 21/133; G01R 25/00; H02P 21/00; H02P 21/14; H02P 21/24; H02P 27/06

(52) U.S. Cl. CPC G06F 1/26; G01R 21/1331; H02P 21/0003; H02P 21/14; H02P 21/24; H02P 27/06; G01R 25/00

(57) ABSTRACT

To provide a power conversion device capable of realizing stable and highly-accurate control of a magnet motor. A processor of a power conversion device computes a first power (first reactive power) from voltages (voltage command values) and currents (current detection values) of a magnet motor. The processor computes a second power (second reactive power) from electric circuit parameters of the magnet motor, steady components (current detection values) and transient components of the current of the magnet motor, and a frequency estimation value of the magnet motor. The processor estimates a phase deviation (phase error) indicating the deviation (difference) between the phase of control and the phase (phase of the magnet) of the magnetic flux of the magnet motor such that the first power follows the second power. The processor computes the frequency estimation value from the estimation value of the phase deviation.

### CROSS-REFERENCE TO RELATED APPLICATION

The present application claims priority from Japanese application JP 2023-190952, filed on Nov. 8, 2023, the content of which is hereby incorporated by reference into this application.

### BACKGROUND OF THE INVENTION

### 1. Field of the Invention

The present invention relates to a power conversion device.

### 2. Description of the Related Art

As a stable and highly-accurate control method in the low speed range of position sensorless control, as described in U.S. Pat. No. 4,402,600, there is a description of a technique for computing a reactive power and estimating the frequency of a magnet motor on the basis of voltage command values and current detection values given to a power converter, electric circuit parameters of the magnet motor, and a frequency estimation value.

### PRIOR ART DOCUMENT

### Patent Document

Patent Document 1: Patent No. 4402600

### SUMMARY OF THE INVENTION

The method described in U.S. Pat. No. 4,402,600 includes computing two types of reactive powers (Q and Q\hat{ }) and computing a frequency estimation value of an inverter such that the deviation ΔQ therebetween is zero. Since the frequency estimation value can reduce the sensitivity to the winding resistance value of the magnet motor, which change being due to a temperature change, highly-accurate control characteristics can be realized. A first motor frequency is estimated by proportional integral (PI) control by using a reactive power in the low speed range, and a second motor frequency is estimated by the PI control such that a phase error (between the phase of control and the phase of the magnet motor) directly estimated by using an extended induced voltage follows zero in the medium/high speed range. Therefore, when the first motor frequency and the second motor frequency are switched to each other, a torque shock due to a current change may occur if there is a difference between the two frequencies.

An object of the present invention is to provide a power conversion device capable of realizing stable and highly-accurate control of a magnet motor.

In order to achieve the above object, the present invention provides a power conversion device including a processor that computes a first power from a voltage and a current of a magnet motor, computes a second power from electric circuit parameters of the magnet motor, steady components and transient components of the current of the magnet motor, and a frequency estimation value of the magnet motor, estimates a phase deviation indicating a deviation between a phase of control and a phase of a magnetic flux of the magnet motor such that the first power follows the second power, and computes the frequency estimation value from an estimation value of the phase deviation.

According to the present invention, stable and highly-accurate control of a magnet motor can be realized. The problems, configurations, and effects other than those described above will be clarified by the following description of embodiments.

### BRIEF DESCRIPTION OF THE DRAWINGS

FIG. 1 is a configuration diagram of a power conversion device according to an embodiment;

FIG. 2 is a configuration diagram of a phase error estimation computation unit in the high speed range where an extended induced voltage is used;

FIG. 3 is a configuration diagram of a phase error estimation computation unit in the low speed range according to the embodiment;

FIG. 4 is a configuration diagram of a frequency and phase estimation computation unit according to the embodiment;

FIG. 5 depicts control characteristics in the case where an extended induced voltage method in the medium/high speed range is used in the low speed range;

FIG. 6 depicts control characteristics in the case where the present invention is used in the low speed range;

FIG. 7 depicts control characteristics in the case where the present invention is used for switching between the low speed range and the medium/high speed range;

FIG. 8 is a configuration diagram for confirming the manifestation of the present invention;

FIG. 9 is a configuration diagram of a power conversion device according to another embodiment;

FIG. 10 is a configuration diagram of another phase error estimation computation unit in the low speed range according to the embodiment;

FIG. 11 is a configuration diagram of a power conversion device according to still another embodiment;

FIG. 12 is a configuration diagram of another phase error estimation computation unit in the high speed range according to the embodiment;

FIG. 13 is a configuration diagram of a power conversion device according to still another embodiment;

FIG. 14 is a configuration diagram of still another phase error estimation computation unit in the high speed range according to the embodiment;

FIG. 15 is a configuration diagram of another power conversion device according to the embodiment; and

FIG. 16 is a configuration diagram of still another power conversion device according to the embodiment.

### DESCRIPTION OF THE PREFERRED EMBODIMENTS

In position sensorless control in which an encoder for detecting the magnet phase of a magnet motor and the like are omitted, the present embodiments realize stable and highly-accurate control characteristics even in a low speed range of, for example, approximately 10% of the base frequency from a stop. In the present embodiments, a phase error is estimated from the deviation between two types of reactive powers in the low speed range as is the case with the medium/high speed range. By estimating a motor frequency such that the estimation value of the relevant phase error follows the command value thereof, a torque shock is prevented and stable and highly-accurate control characteristics are realized without adjusting electric circuit parameters and control gains of the magnet motor set in a controller.

It should be noted that the present embodiments will be described below in detail by using the drawings. The same reference characters (signs) are given to the common configurations in each drawing. In addition, each embodiment to be described below is not limited to the illustrated examples.

### First Embodiment

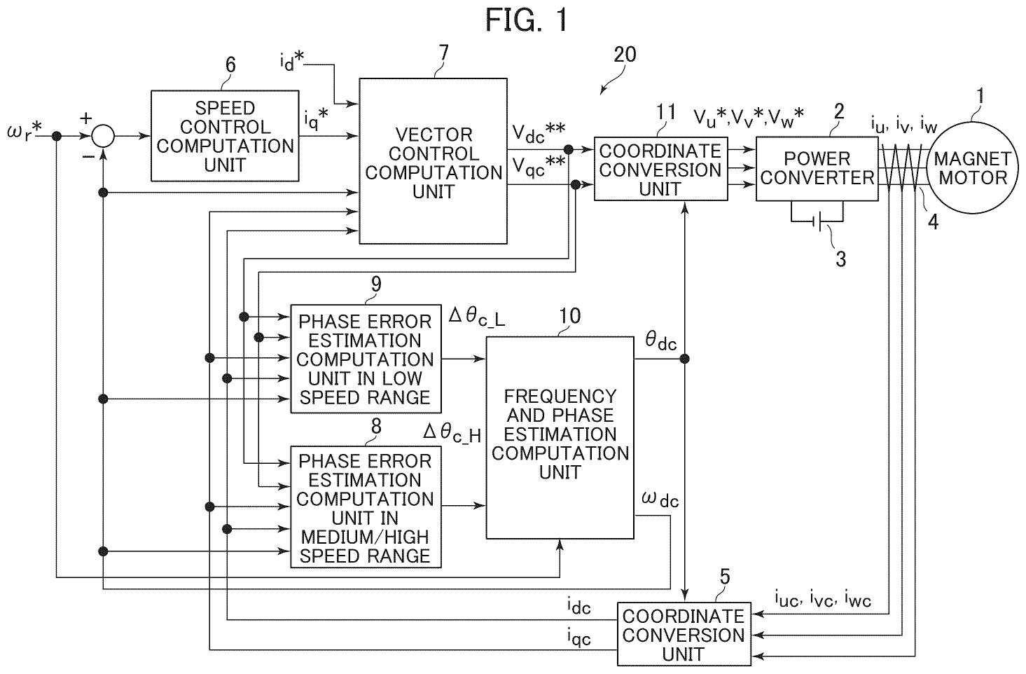

FIG. 1 depicts a configuration diagram of a power conversion device according to an embodiment.

A magnet motor 1 outputs a motor torque obtained by combining a torque component due to the magnetic flux of a permanent magnet and a torque component due to the inductance of an armature winding.

A power converter 2 outputs voltage values proportional to voltage command values vᵤ*, vᵥ*, and v_{w}* of three-phase AC, and varies an output voltage value and an output frequency value to the magnet motor 1. Although the power converter 2 of the present embodiment includes a controller (microcomputer or the like), a power conversion device 20 described later may include a controller. The controller is configured using a memory (storage device), a CPU (processor), an input/output circuit (communication device), and the like.

A DC power supply 3 supplies a DC voltage to the power converter 2.

A current detector 4 outputs i_{uc}, i_{vc}, and i_{wc} that are the detection values of three-phase AC currents iᵤ, iᵥ, and i_{w} of the magnet motor 1. In addition, the current detector 4 detects the AC currents of two phases among the three phases of the magnet motor 1, which are the u phase and the w phase, for example, and the AC current of the v phase may be obtained from the AC condition (iᵤ+iᵥ+i_{w}=0) as iᵥ=−(iᵤ+i_{w}).

A coordinate conversion unit 5 outputs current detection values i_{dc} and i_{qc} of the d axis and the q axis from the detection values i_{uc}, i_{vc}, and i_{wc} of the three-phase AC currents iᵤ, iᵥ, and i_{w} and a phase estimation value θ_{dc}.

A speed control computation unit 6 computes a torque command value t* on the basis of a frequency command value ωᵣ* and a frequency estimation value ω_{dc}, and divides it by a torque coefficient, so that a current command value i_{q}* of the q axis is output.

A vector control computation unit 7 outputs voltage command values v_{dc}* and v_{qc}** of the d axis and the q axis computed on the basis of the current command values i_{d}* and i_{q}* and the current detection values i_{dc} and i_{qc} of the d axis and the q axis, the frequency estimation value ω_{dc}, and electric circuit parameters of the magnet motor 1.

A phase error estimation computation unit 8 in the medium/high speed range outputs an estimation value Δθ_{c_H} of a phase error Δθ, which is the deviation between the phase θ_{dc} of control and the phase θ_{d} of the magnet of the magnet motor 1 in the medium/high speed range, by using voltage command values v_{dc}* and v_{qc} of the d_{c} axis and the q_{c} axis that are the control axes, the frequency estimation value ω_{dc}, the current detection values i_{dc} and i_{qc}, and the electric circuit parameters of the magnet motor 1.

A phase error estimation computation unit 9 in the low speed range computes an estimation value Δθ_{c_L} of the phase error Δθ, which is the deviation between the phase θ_{dc} of control and the phase θ_{d} of the magnet of the magnet motor 1 in the low speed range, by using the voltage command values v_{dc}* and v_{qc} of the d_{c} axis and the q_{c} axis that are the control axes, the frequency estimation value ω_{dc}, the current detection values i_{dc} and i_{qc}, and the electric circuit parameters of the magnet motor 1.

A frequency and phase estimation computation unit 10 outputs the frequency estimation value ω_{dc} and the phase estimation value θ_{dc} on the basis of the estimation value Δθ_{c_L} of the phase error in the low speed range or the estimation value Δθ_{c_H} of the phase error in the medium/high speed range.

A coordinate conversion unit 11 outputs the voltage command values v_{dc}* and v_{qc} of the d_{c} axis and the q_{c} axis and the voltage command values vᵤ*, vᵥ*, and v_{w}* of the three-phase AC from the phase estimation value θ_{dc}.

First, the basic operation of a sensorless vector control system in the case where the phase error estimation computation unit 9 in the low speed range, which is a feature of the present embodiment, is used will be described.

The speed control computation unit 6 computes the torque command t* and the current command value i_{q}* of the q axis in accordance with Equation (1) by proportional control and integral control such that a frequency estimation value ωr\hat{ }(=ω_{dc}) follows the frequency command value ωᵣ*. It should be noted that in the following various equations, the frequency estimation value will be described as ωᵣ\hat{ } or ω_{dc} in some cases.

$$\begin{matrix}[ Equation 1 ] & \\ \begin{matrix}{τ}^{⋆} = ( {ω}_{r}^{*} - {ω}_{r}^{∧} ) ( {K}_{sp} + \frac{{K}_{si}}{s} ) \\ {i}_{q}^{*} = \frac{{τ}^{*}}{3 / 2 {P}_{m} [ {K}_{e}^{*} + ( {L}_{d}^{*} - {L}_{q}^{*} ) {i}_{d}^{*} ]}\end{matrix} ) & ( 1 )\end{matrix}$$

Here, Kₛₚ is a proportional gain of speed control, Kₛᵢ is an integral gain of speed control, Pₘ is the number of pole pairs, Kₑ is an induced voltage coefficient, L_{d} is a d-axis inductance, L_{q} is a q-axis inductance, and * is a set value.

First, the vector control computation unit 7 outputs voltage reference values v_{dc}* and v_{qc} of the d_{c} axis and the q_{c} axis in accordance with Equation (2) by using a set value R* of the winding resistance that is an electric circuit parameter of the magnet motor 1, a set value L_{d}* of the d-axis inductance, a set value L_{q}* of the q-axis inductance, a value Kₑ* of the induced voltage coefficient, the current command values i_{d}* and i_{q}* of the d_{c} axis and the q_{c} axis, and the frequency estimation value ωᵣ\hat{ } (=ω_{dc}).

$$\begin{matrix}[ Equation 2 ] & \\ [ \begin{matrix}{v}_{dc}^{*} = {R}^{*} {i}_{d}^{*} - {ω}_{dc} {L}_{q}^{*} \frac{1}{1 + {T}_{acr S}} {i}_{q}^{*} \\ {v}_{qc}^{*} = {R}^{*} {i}_{q}^{*} + {ω}_{dc} ( {L}_{d}^{*} \frac{1}{1 + {T}_{acr S}} {i}_{d}^{*} + {K}_{e}^{*} )\end{matrix} ] & ( 2 )\end{matrix}$$

Here, T_{acr} is a response time constant of current control.

Second, the vector control computation unit 7 computes voltage correction values Δv_{dc} and Δv_{qc} of the d_{c} axis and the q_{c} axis in accordance with Equation (3) by proportional control and integral control such that the current detection values i_{dc} and i_{qc} of each component follow the current command values i_{d}* and i_{q}* of the d_{c} axis and the q_{c} axis.

$$\begin{matrix}[ Equation 3 ] & \\ [ \begin{matrix}Δ {v}_{dc} = ( {K}_{pd} + \frac{{K}_{id}}{s} ) ( {i}_{d}^{*} - {i}_{dc} ) \\ Δ {v}_{qc} = ( {K}_{pq} + \frac{{K}_{iq}}{s} ) ( {i}_{q}^{*} - {i}_{qc} )\end{matrix} ] & ( 3 )\end{matrix}$$

Here, K_{pd} is a proportional gain of current control of the d_{c} axis, K_{id} is an integral gain of current control of the d_{c} axis, K_{pq} is a proportional gain of current control of the q_{c} axis, and K_{iq} is an integral gain of current control of the qc axis. The vector control computation unit 7 further computes the voltage command values v_{dc}* and v_{qc} of the d_{c} axis and the qc axis in accordance with Equation (4).

$$\begin{matrix}[ Equation 4 ] & \\ [ \begin{matrix}{v}_{dc}^{**} = {v}_{dc}^{*} + Δ {v}_{dc} \\ {v}_{qc}^{**} = {v}_{qc}^{*} + Δ {v}_{qc}\end{matrix} ] & ( 4 )\end{matrix}$$

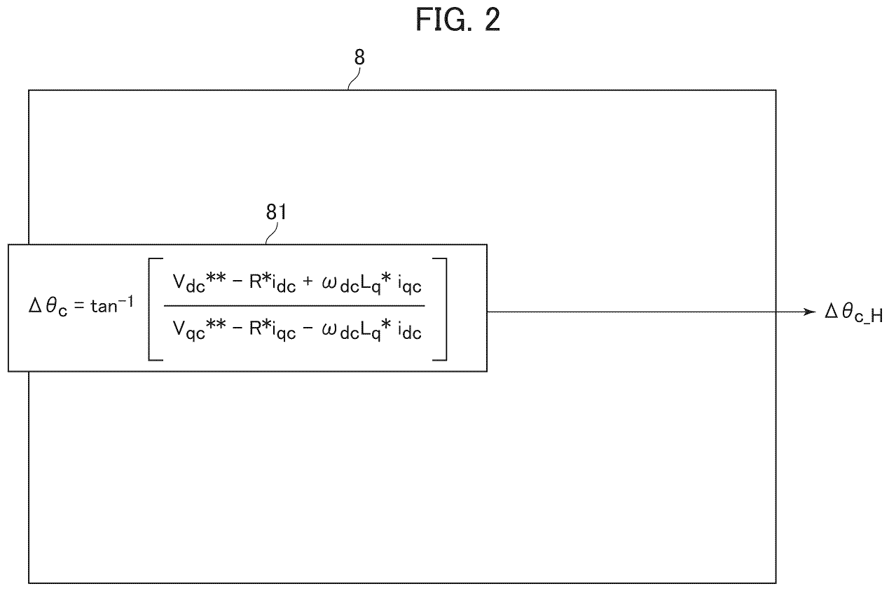

FIG. 2 depicts a block of the phase error estimation computation unit 8 in the medium/high speed range. The phase error estimation computation unit 8 in the medium/high speed range computes the estimation value Δθ_{c_H} the phase error in the medium/high speed range in accordance with Equation (5) of an extended induced voltage denoted by the reference numeral 81, on the basis of the voltage command values v_{dc}** and v_{qc}** and the current detection values i_{dc} and i_{qc} of the d_{c} axis and the q_{c} axis, and the electric circuit parameters (R* and L_{q}*) of the magnet motor 1.

$$\begin{matrix}[ Equation 5 ] & \\ Δ {θ}_{c \_ H} = {tan}^{- 1} ( \frac{{v}_{dc}^{**} - {R}^{*} {i}_{dc} + {ω}_{dc} {L}_{q}^{*} {i}_{qc}}{{v}_{qc}^{**} - {R}^{*} {i}_{qc} - {ω}_{dc} {L}_{q}^{*} {i}_{dc}} ) & ( 5 )\end{matrix}$$

Here, the phase error estimation computation unit 9 in the low speed range, which is a feature of the present embodiment of the present invention, will be described.

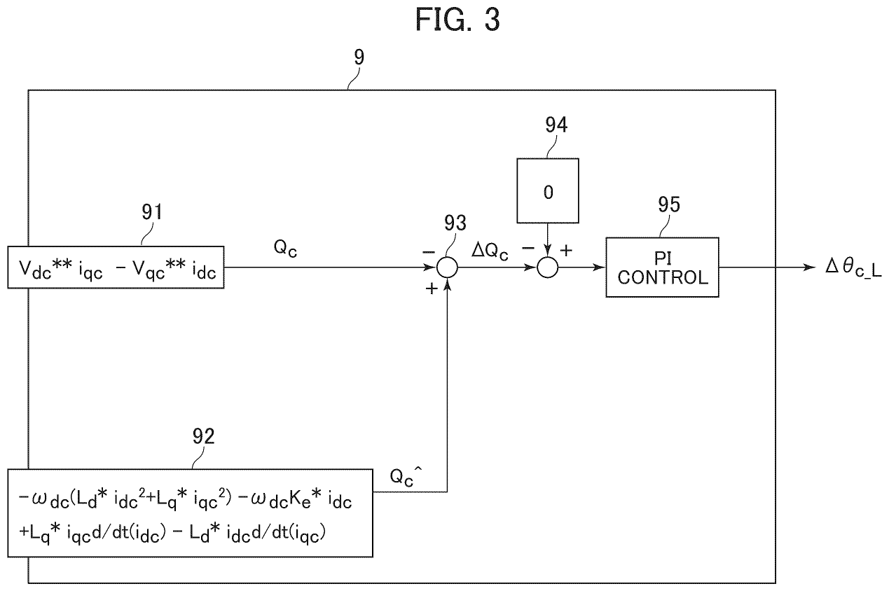

FIG. 3 depicts a block of the phase error estimation computation unit 9 in the low speed range. The phase error estimation computation unit 9 in the low speed range computes a first reactive power Qc in accordance with Equation (6) by using the voltage command values v_{dc}** and v_{qc}** and the current detection values i_{dc} and i_{qc} of the d_{c} axis and the qc axis in a first reactive power computation unit 91.

$$\begin{matrix}[ Equation 6 ] & \\ {Q}_{c} = {v}_{dc}^{**} {i}_{qc} - {v}_{qc}^{**} {i}_{dc} & ( 6 )\end{matrix}$$

A second reactive power computation unit 92 computes a second reactive power Q_{c}\hat{ } in accordance with Equation (7) by using steady components i_{dc} and i_{qc} and transient components dt/d(i_{dc}) and dt/d(i_{qc}) of the current detection values of the d_{c} axis and the qc axis, the frequency estimation value ω_{dc}, and the electric circuit parameters (L_{d}*, L_{g}*, and Kₑ*) of the magnet motor 1.

$$\begin{matrix}[ Equation 7 ] & \\ {Q}_{c}^{∧} = - {ω}_{dc} ( {L}_{d}^{*} {i}_{dc}^{2} + {L}_{q}^{*} {i}_{qc}^{2} ) - {ω}_{dc} {K}_{e}^{*} + {L}_{d}^{*} {i}_{dc} + {L}_{d}^{*} {i}_{c} d / dt ( {i}_{dc} ) - {L}_{q}^{*} {i}_{dc} d / dt ( {i}_{qc} ) & ( 7 )\end{matrix}$$

A subtraction unit 93 receives inputs of the first reactive power Q_{c} and the second reactive power Q_{c}\hat{ }, and computes ΔQ_{c} as the deviation therebetween. The deviation ΔQ_{c} between the reactive powers is input to a PI control computation unit 95 so as to follow “0” that is a command value 94 thereof, and the estimation value Δθ_{c_L} of the phase error Δθ in the low speed range is computed in accordance with Equation (8) by proportional (P)+integral (I) control computation.

$$\begin{matrix}[ Equation 8 ] & \\ {Δθ}_{c \_ L} = ( {K}_{p θ} + \frac{{K}_{i θ}}{s} ) ( 0 - Δ {Q}_{c} ) & ( 8 )\end{matrix}$$

Here, K_{pθ} is a proportional gain of phase error estimation computation, and K_{iθ} is an integral gain of phase error estimation computation.

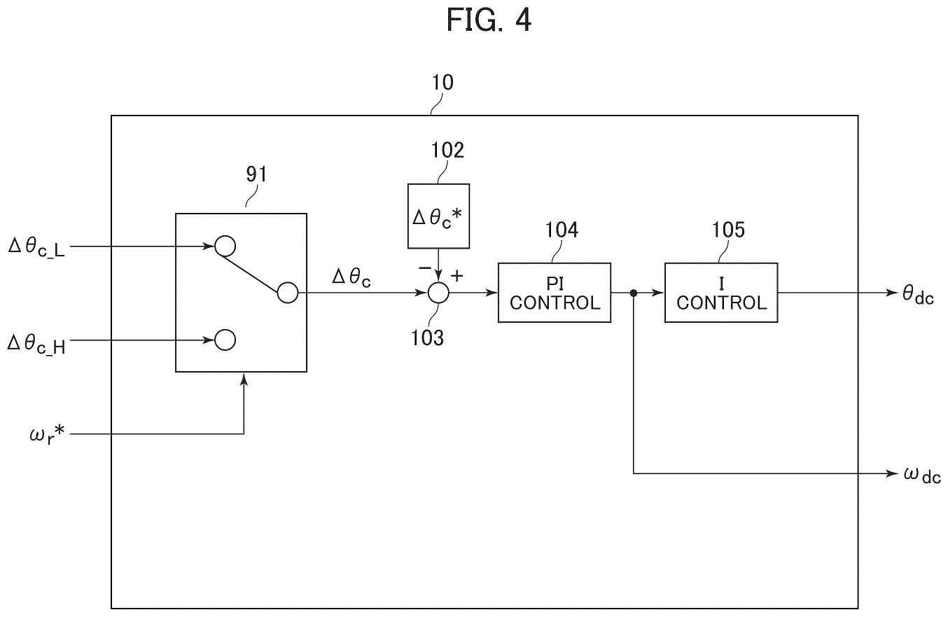

In addition, the frequency and phase estimation computation unit 10, which is a feature of the embodiment of the present invention, will be described. FIG. 4 depicts a block of the frequency and phase estimation computation unit 10.

A switching unit 101 receives inputs of the estimation value Δθ_{c_L} of the phase error in the low speed range, the estimation value Δθ_{c_H} of the phase error in the medium/high speed range, and the frequency command value ωᵣ*, and outputs Δθ_{c}=Δθ_{c_L} in the case of the low speed range and Δθ_{c}=Δθ_{c_H} in the case of the medium/high speed range, as the estimation value Δθ_{c} of the phase error according to the magnitude of the frequency command value ωᵣ*.

The subtraction unit 103 inputs the estimation value Δθ_{c} of the phase error described above to the PI control computation unit 104 so as to follow the command value Δθ_{c}* denoted by the reference numeral 102, the frequency estimation value ω_{dc} is computed in accordance with Equation (9) by the proportional (P)+integral (I) computation, and the phase estimation value θ_{dc} is computed in accordance with Equation (10) by an I control computation unit 105.

$$\begin{matrix}[ Equation 9 ] & \\ {ω}_{dc} = ( {Kp}_{pll} + \frac{{Ki}_{pll}}{s} ) ( Δ {θ}_{c}^{*} - Δ {θ}_{c} ) & ( 9 )\end{matrix}$$

$$\begin{matrix}[ Equation 10 ] & \\ θ dc = \frac{1}{s} \cdot {ω}_{dc} & ( 10 )\end{matrix}$$

Here, Kₚₚₗₗ is a proportional gain of PLL control, and Kiₚₗₗ is an integral gain of PLL control.

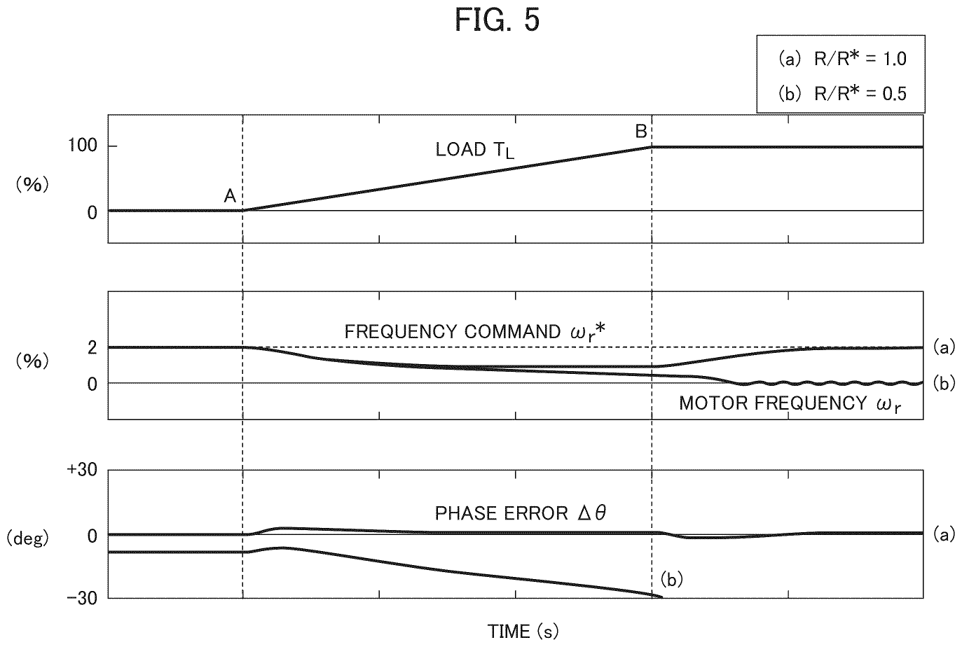

Next, the principle in which the embodiment of the present invention provides stable and highly-accurate control characteristics will be described. FIG. 5 depicts control characteristics in the case where the phase error estimation computation unit 9 in the low speed range of the present invention is not used (Δθ_{c_H} is used). The frequency command value ωᵣ* is set to 2% of the base frequency. FIG. 5 depicts simulation results of (a) R*/R=1 (reference) when there is no error and (b) R*/R=0.5 when there is an error, in the voltage command values v_{dc}* and v_{dc}* of the d_{c} axis and the q_{c} axis depicted in Equation (2) and the set value R* of the resistance value R included in the computation formula of the phase error in the medium/high speed range depicted in Equation (5).

In the drawing, the upper row indicates a load torque TL, the middle row indicates a frequency command ωᵣ* and a motor frequency ωᵣ, and the lower row indicates a phase error Δθ. In the drawing, the load torque application that starts with the point A of the time is changed in a ramp-like manner to reach 100% at the point B of the time, and then the load torque application state is kept as it is on the right side of the point B.

In the setting of (a) R*/R=1 (reference), the phase error Δθ is zero in the steady state, and the motor frequency ωᵣ matches the frequency command ωᵣ*. In the setting of (b) R*/R=0.5, the phase error Δθ increases to “negative,” the motor frequency or is stagnant around zero, and the magnet motor 1 is stepped out.

In the embodiment of the present invention, the first reactive power Q_{c} is computed in accordance with Equation (6) by using the voltage command values v_{dc}* and v_{qc}* and the current detection values i_{dc} and i_{qc} of the d_{c} axis and the q_{c} axis, and the second reactive power Q_{c}\hat{ } is computed in accordance with Equation (7) by using the steady components i_{dc} and iqc and the transient components dt/d(i_{dc}) and dt/d(i_{qc}) of the current detection values of the d_{c} axis and the q_{c} axis, the frequency estimation value ω_{dc}, and the set values (L_{d}*, L_{q}*, and Kₑ*) of the electric circuit parameters of the magnet motor 1. By automatically adjusting the estimation value Δθ_{c_L} of the phase error in the low speed range in accordance with Equation (8) such that the deviation between Q_{c}\hat{ } and Q_{c} follows zero, and by using the estimation value Δθ_{c_L} in the frequency and phase estimation computation unit 10, the sensitivity to the resistance value can be reduced and the control characteristics can be improved.

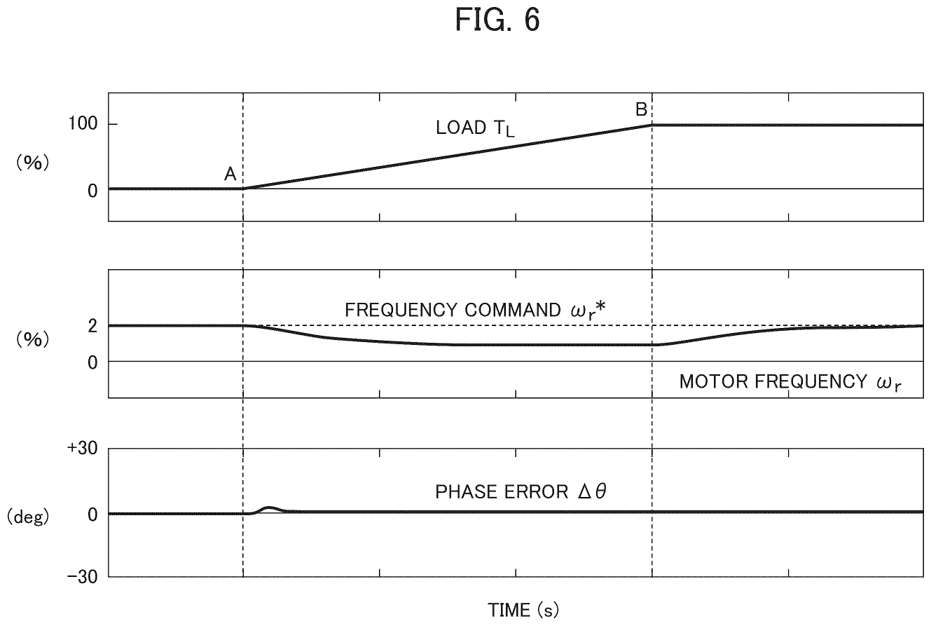

FIG. 6 depicts control characteristics in the low speed range according to the present embodiment. In the setting of R*/R=0.5, the phase error estimation computation unit 9 in the low speed range and the frequency and phase estimation computation unit 10 are operated to apply the load torque similar to that in FIG. 4. Since the estimation value Δθ_{c_L} of the phase error is computed from the reactive power that is less sensitive to the resistance value R, the actual phase error Δθ can be suppressed to zero even in the setting of R*/R=0.5.

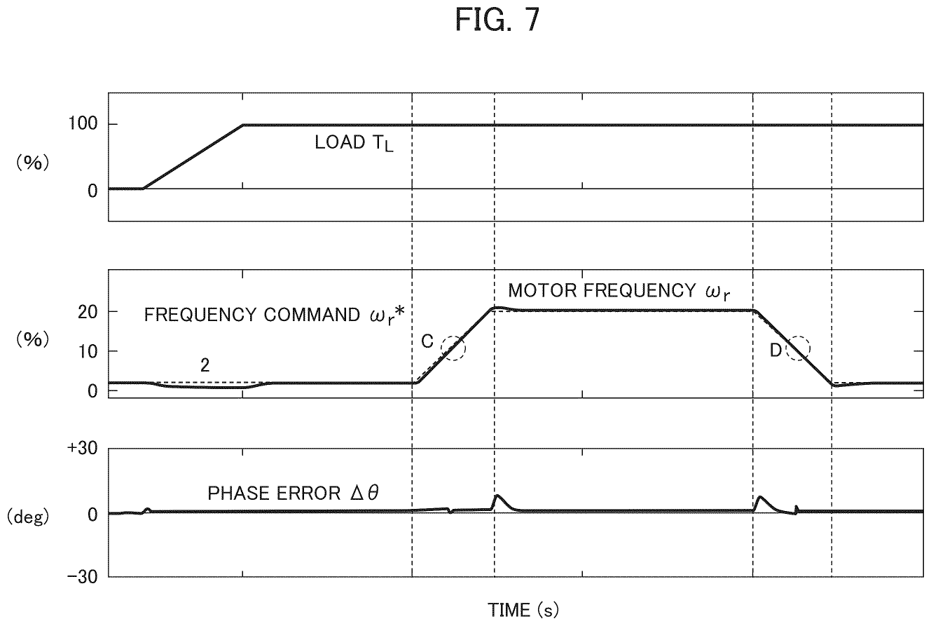

Further, FIG. 7 depicts control characteristics in which the frequency command value ωᵣ* is accelerated from 2% to 20% of the base frequency and decelerated from 20% to 2% by using the present invention. At this time, ωᵣ* is 10% in magnitude, and the estimation value of the phase error is switched between the low speed range and the medium/high speed range. The estimation value of the phase error is computed in accordance with Equations (6) to (8) in the low speed range where ωᵣ* is less than 10%, and is computed in accordance with Equation (5) in the medium/high speed range where ωᵣ* is equal to or more than 10%.

The speed is switched from the low speed range to the medium/high speed range in the region C of the drawing, and the speed is switched from the medium/high speed range to the low speed range in the region D. Viewing the phase error Δθ in the lower row, it can be understood that there is no shock in the motor frequency ωᵣ although the magnitude slightly changes at the switching timing, and the effect of the embodiment of the present invention is obvious.

In the present embodiment, as an example, ωᵣ* is 10% in magnitude, and the estimation value of the phase error is switched between the low speed range and the medium/high speed range, but there is no problem even if the value is 0 or more and 10% or less. In addition, the estimation value Δθ_{c_L} of the phase error in the low speed range is multiplied by a taper gain G_{_L} that changes between “1” and “0”, and the estimation value Δθ_{c_H} of the phase error in the medium/high speed range is multiplied by a taper gain G_{_H} that changes between “0” and “1”, so that the average value of the estimation values of the phase error may be Δθ_{c}.

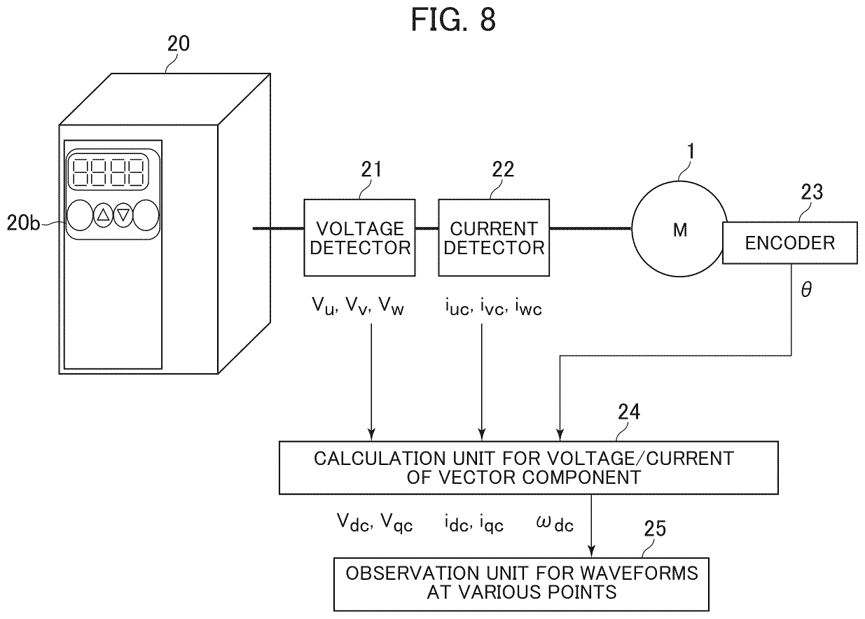

Here, a verification method in the case where the present embodiment is adopted will be described by using FIG. 8. A voltage detector 21 and a current detector 22 are attached to the power conversion device 20 that drives the magnet motor 1, and an encoder 23 is attached to the shaft of the magnet motor 1. It should be noted that the power conversion device 20 includes the power converter 2, a digital operator 20b (user interface serving as an input device and a display device), and the like.

The voltage detection values (v_{uc}, v_{vc}, and v_{wc}) of the three-phase AC, which are the outputs of the voltage detector 21, the current detection values (i_{uc}, i_{vc}, and i_{wc}) of the three-phase AC, and the position θ, which is the output of the encoder, are input to a calculation unit 24 for voltage/current of the vector component, and a detection value ω_{rc} is computed, which is obtained by differentiating the vector voltage components v_{dc} and v_{qc}, the vector current components i_{dc} and i_{qc}, and the position θ.

A phase error Δθ__{cal} is computed by using Equation (11) in an observation unit 25 for waveforms at various points.

$$\begin{matrix}[ Equation 11 ] & \\ Δθ\_ca1 = \frac{- b \pm \sqrt{{b}^{2} - 4 a c}}{2 a} a = ( {L}_{d} - {L}_{q} ) ( {i}_{qc}^{2} - {i}_{d c}^{2} ) b = ( 2 ( {L}_{d} - {L}_{q} ) {i}_{d c}^{2} + {K}_{e} ) {i}_{qc} c = ( {L}_{q}^{*} - {L}_{q} ) {i}_{qc}^{2} - ( {L}_{d}^{*} - {L}_{d} ) {i}_{d c}^{2} - ( {K}_{e}^{*} - {K}_{e} ) {i}_{d c} & ( 11 )\end{matrix}$$

It is obvious that the present invention has been adopted if Δθ__{cal} in Equation (11), which is computed by changing the magnitudes of the parameters (R*, L_{d}*, L_{q}*, and Kₑ*) set in the controller of the power converter 2, matches the actual phase error Δθ.

The main features of the first embodiment can also be summarized as follows.

As depicted in FIG. 3, the processor of the power conversion device 20 computes the first power (first reactive power Q_{c}) from the voltages (voltage command values v_{dc}** and v_{qc}**) and the currents (current detection values i_{dc} and i_{qc}) of the magnet motor 1 (Equation (6)). The processor computes the second power (second reactive power Q_{c}\hat{ }) from the electric circuit parameters (L_{d}*, L_{q}*, and Kₑ*) of the magnet motor 1, the steady components (current detection values i_{dc} and i_{qc}) and the transient components dt/d(i_{dc}) and dt/d(i_{qc}) of the current of the magnet motor 1, and the frequency estimation value ω_{dc} of the magnet motor 1 (Equation (7)). The processor estimates the phase deviation (phase error Δθ) indicating the deviation (difference) between the phase θ_{dc} of control and the phase (phase θ_{d} of the magnet) of the magnetic flux of the magnet motor such that the first power follows the second power. As depicted in FIG. 4, the processor computes the frequency estimation value ω_{dc} from the estimation values (Δθ_{c_L} and Δθ_{c_H}) of the phase deviation. In the present embodiment, the first power and the second power are reactive powers.

Since the second power includes the transient components of the current of the magnet motor 1, the accuracy of the phase deviation (phase error Δθ) and the frequency estimation value ω_{dc} is secured even when the frequency of the magnet motor 1 is switched. Accordingly, stable and highly-accurate control characteristics can be realized without adjusting the electric circuit parameters and the control gains of the magnet motor 1. In addition, even if the responsiveness of the speed control is enhanced, the oscillation of the current (q-axis current) when the frequency of the magnet motor 1 is switched is suppressed. Accordingly, a torque shock can be suppressed. Since the first power and the second power do not include the winding resistance value, the deterioration of the accuracy of the phase deviation (phase error Δθ) and the frequency estimation value ω_{dc} due to a change in the winding resistance value accompanying a temperature change in the low speed range is suppressed. Accordingly, highly-accurate control of the magnet motor 1 can be realized regardless of the temperature change.

More specifically, as depicted in FIG. 3, the processor computes the first power (first reactive power Q_{c}) from the difference (v_{dc}**i_{qc}-v_{qc}**i_{dc}) between the products of the voltage command values and the current detection values of the different components of the d axis, which is the magnetic flux axis of the magnet motor 1, and the q axis, which is the torque axis of the magnet motor 1. The processor computes the second power (second reactive power Q_{c}\hat{ }) from the electrical circuit parameters (L_{d}*, L_{q}*, and Kₑ*), the steady components (current detection values i_{dc} and i_{qc}) and the transient components dt/d(i_{dc}) and dt/d(i_{qc}) of the current detection values or the current command values of the d axis and the q axis, and the frequency estimation value ω_{dc}. Accordingly, stable and highly-accurate control of the magnet motor 1 can be realized in the power conversion device of the vector control.

In the present embodiment, the processor computes the estimation value Δθ_{c_L} of the phase deviation (phase error Δθ) by performing proportional control and integral control such that the power deviation (deviation ΔQ_{c} between the reactive powers) indicating the deviation between the first power (first reactive power Q_{c}) and the second power (second reactive power Q_{c}\hat{ }) is zero. Accordingly, the estimation value Δθ_{c_L} of the phase deviation (phase error Δθ) can be computed on the basis of the power deviation.

As depicted in FIG. 3, the processor computes the estimation value Δθ_{c_L} of the phase deviation by performing proportional control and integral control such that the power deviation (deviation ΔQ_{c}) between the reactive powers is zero in the low speed range where the frequency command value ωᵣ* is less than a threshold value. As depicted in FIG. 2, the processor computes the estimation value Δθ_{c_H} of the phase deviation by using an extended induced voltage method in the medium/high speed range where the frequency command value ωᵣ* is equal to or larger than a threshold value. Accordingly, stable and highly-accurate control of the magnet motor 1 can be realized in all the speed ranges.

### Second Embodiment

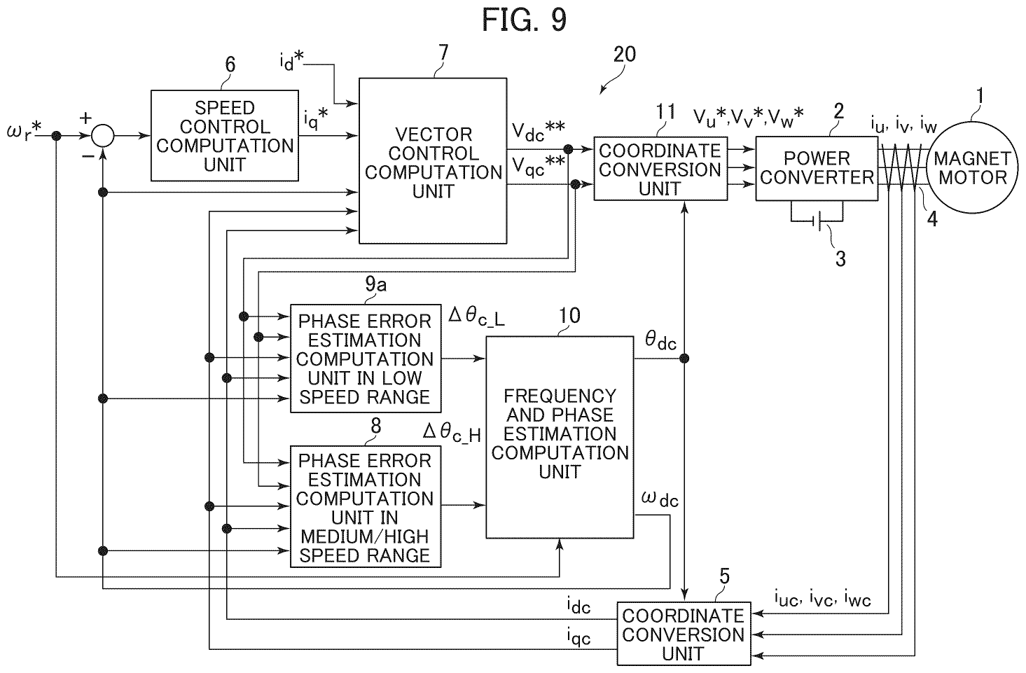

FIG. 9 is a configuration diagram of a power conversion device according to an embodiment.

In the first embodiment, the phase error estimation computation unit 9 in the low speed range computes the first reactive power Q_{c} from the voltage command values v_{dc}** and v_{qc}** and the current detection values i_{dc} and i_{qc} of the d_{c} axis and the qc axis, but in the present embodiment, the first reactive power Q_{c} is computed by using an amplitude value V₁* of the voltage command of the three-phase AC, an amplitude value i₁ of the current detection value, and a sine signal of a phase θᵥ₁. The reference numerals 1 to 8, 10, and 11 in the drawing are the same as those in FIG. 1.

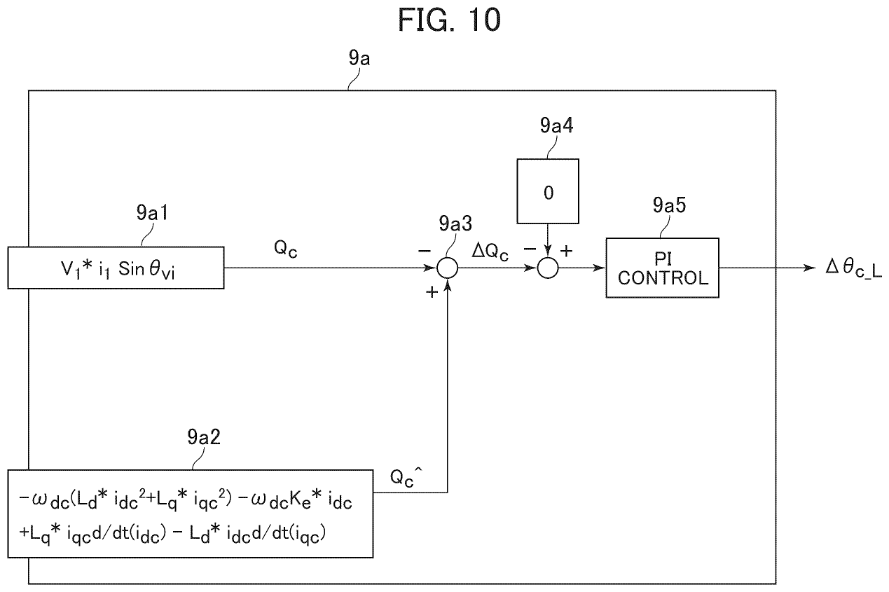

FIG. 10 is a configuration diagram of a phase error estimation computation unit 9a in the low speed range of the embodiment of the present invention. The reference numeral 9a of the drawing corresponds to the reference numeral 9 in FIG. 1. In addition, the reference numerals 9a2, 9a3, 9a4, and 9a5 in FIG. 10 are the same as the reference numerals 92, 93, 94, and 95 in FIG. 3, respectively. In the drawing, in 9a1, the amplitude value V₁* of the voltage command of the three-phase AC is obtained in accordance with Equation (12), the amplitude value i₁ of the current detection value is obtained in accordance with Equation (13), the phase θᵥ₁ is obtained in accordance with Equation (14), and the reactive power Q_{c} is computed by using Equation (15).

$$\begin{matrix}[ Equation 12 ] & \\ {v}_{1}^{*} = \sqrt{{v}_{d c}^{** 2} + {v}_{qc}^{** 2}} & ( 12 )\end{matrix}$$

$$\begin{matrix}[ Equation 13 ] & \\ {i}_{1} = \sqrt{{i}_{d c}^{2} + {i}_{qc}^{2}} & ( 13 )\end{matrix}$$

$$\begin{matrix}[ Equation 14 ] & \\ {θ}_{vi} = {tan}^{- 1} [ - \frac{{v}_{d c}}{{v}_{qc}} ] + {tan}^{- 1} [ - \frac{{i}_{d c}}{{i}_{qc}} ] & ( 14 )\end{matrix}$$

$$\begin{matrix}[ Equation 15 ] & \\ {Q}_{c} = {v}_{1}^{*} {i}_{1} sin [ {θ}_{vi} ] & ( 15 )\end{matrix}$$

Even if the present embodiment is used, highly-accurate control characteristics can be realized as similar to the first embodiment.

The main features of the second embodiment can also be summarized as follows.

As depicted in FIG. 10, the processor of the power conversion device 20 computes the first power (first reactive power Q_{c}) from the product of the voltage amplitude value (amplitude value V₁* of the voltage command) of one phase of the three-phase AC, the current amplitude value (amplitude value i₁ of the current detection value) of the phase, and the sine signal sin [θᵥ₁] of the phase difference between the voltage command value and the current detection value of the phase (Equation (15)). The processor computes the second power (second reactive power Q_{c}\hat{ }) from the electrical circuit parameters (L_{d}*, L_{q}*, and Kₑ*), the steady components (current detection values i_{dc} and i_{qc}) and the transient components dt/d(i_{dc}) and dt/d(i_{qc}) of the current detection values or the current command values of the d axis and the q axis, and the frequency estimation value ω_{dc}. Stable and highly-accurate control of the magnet motor 1 can be realized on the basis of the sine signal of the three-phase AC.

### Third Embodiment

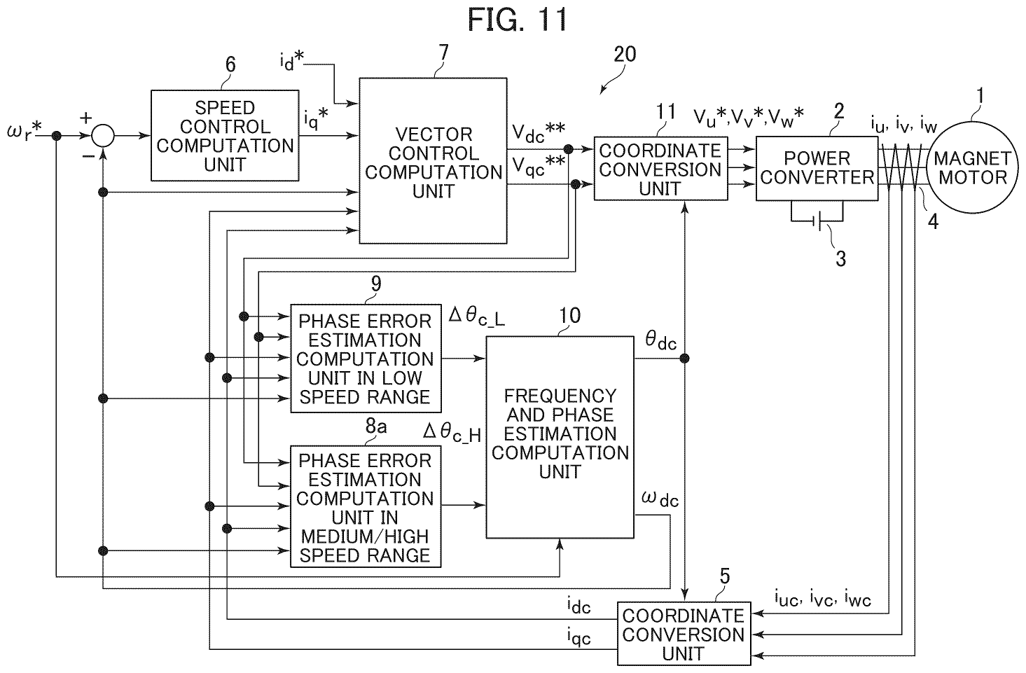

FIG. 11 is a configuration diagram of a power conversion device according to an embodiment.

In the first embodiment, the phase error estimation computation unit 8 in the medium/high speed range computes the estimation value Δθ_{c_H} of the phase error in the medium/high speed range in accordance with Equation (5), but in the third embodiment, a first active power Pc is computed from the voltage command values v_{dc}** and v_{qc}** and the current detection values i_{dc} and i_{qc} of the d_{c} axis and the q_{c} axis.

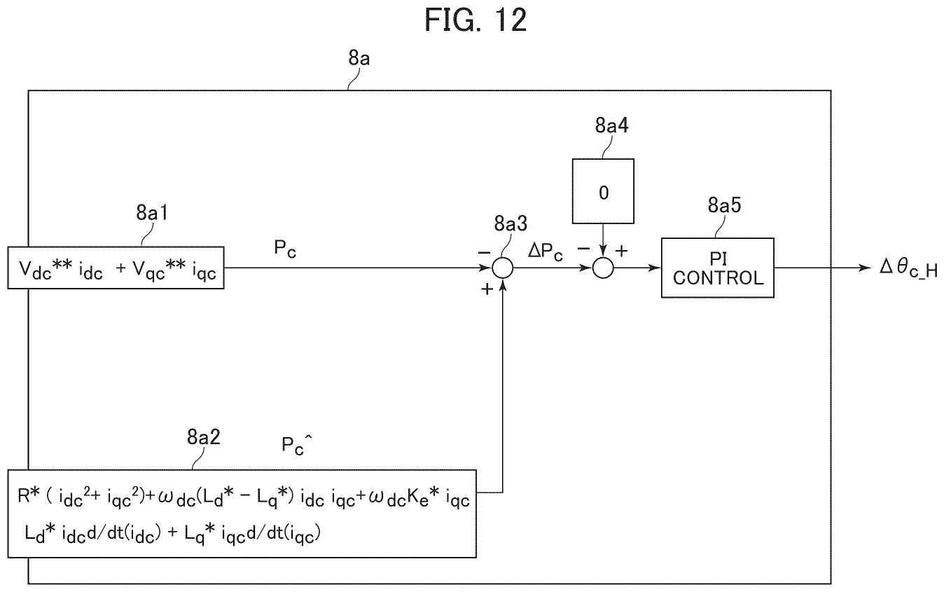

FIG. 12 is a phase error estimation computation unit 8a in the medium/high speed range of the embodiment of the present invention. The reference numeral 8a of the drawing corresponds to the reference numeral 8 in FIG. 1. The reference numerals 1 to 7 and 9 to 11 in the drawing are the same as those in FIG. 1.

In the phase error estimation computation unit 8a of the drawing, a first active power computation unit 8al computes the first reactive power Pc in accordance with Equation (16) by using the voltage command values v_{dc}** and v_{qc}** and the current detection values i_{dc} and i_{qc} of the d_{c} axis and the q_{c} axis.

$$\begin{matrix}[ Equation 16 ] & \\ {p}_{c} = {v}_{d c}^{**} {i}_{d c} + {v}_{qc}^{**} {i}_{q c} & ( 16 )\end{matrix}$$

A second active power computation unit 8a2 computes a second active power Pₑ\hat{ } in accordance with Equation (17) by using the steady components i_{dc} and i_{qc} and the transient components dt/d(i_{dc}) and dt/d(i_{qc}) of the current detection values of the d_{c} axis and the q_{c} axis, the frequency estimation value ω_{dc}, and the electric circuit parameters (R*, L_{d}*, L_{q}*, and Kₑ*) of the magnet motor 1.

$$\begin{matrix}[ Equation 17 ] & \\ {P}_{c}^{\hat{}} = {R}^{*} ( {i}_{d c}^{2} + {i}_{q c}^{2} ) + d / dt ( {i}_{d c} ) {L}_{d}^{*} {i}_{d c} + d / dt ( {i}_{qc} ) {L}_{q}^{*} {i}_{q c} + {ω}_{d c} ( {L}_{d}^{*} - {L}_{q}^{*} ) {i}_{d c} {i}_{q c} + {ω}_{d c} {K}_{e}^{*} {i}_{q c} & ( 17 )\end{matrix}$$

A subtraction unit 8a3 receives inputs of the first active power P_{c} and the second active power P_{c}\hat{ }, and computes ΔP_{c} as the deviation therebetween. The deviation ΔP_{c} between the active powers is input to a PI control computation unit 8a5 so as to follow “0” that is a command value 8a4 thereof, and the estimation value Δθ_{c_H} of the phase error Δθ in the high speed range is computed in accordance with Equation (18) by P (proportional)+I (integral) control.

$$\begin{matrix}[ Equation 18 ] & \\ {Δθ}_{c \_ H} = ( {K}_{p θ} + \frac{{K}_{i θ}}{s} ) ( 0 - Δ {P}_{c} ) & ( 18 )\end{matrix}$$

Here, K_{pθ} is a proportional gain of phase error estimation computation, and K_{iθ} is an integral gain of phase error estimation computation.

The main features of the third embodiment can also be summarized as follows.

As depicted in FIG. 12, the processor of the power conversion device 20 computes the first power (first active power P_{c}) from the sum (v_{dc}**i_{qc}+v_{qc}**i_{dc}) of the products of the voltage command values and the current detection values of the same component of the d axis, which is the magnetic flux axis of the magnet motor 1, and the q axis, which is the torque axis of the magnet motor 1 (Equation (16)). The processor computes the second power (second active power P_{c}\hat{ } from the electrical circuit parameters (R*, L_{d}*, L_{q}*, and Kₑ*), the steady components (current detection values i_{dc} and i_{qc}) and the transient components dt/d(i_{dc}) and dt/d(i_{qc}) of the current detection values or the current command values of the d axis and the q axis, and the frequency estimation value ω_{dc} (Equation (17)). In the present embodiment, the first power and the second power are active powers.

Accordingly, in the power conversion device of the vector control, the estimation value Δθ_{c_H} of the phase deviation in the medium/high speed range can be computed on the basis of the active powers instead of the conventional extended induced voltage method.

As similar to the first embodiment, the processor computes the estimation value Δθ_{c_L} of the phase deviation by performing proportional control and integral control such that the power deviation (deviation ΔQ_{c}) between the reactive powers is zero in the low speed range where the frequency command value ωᵣ* is less than a threshold value (FIG. 4 and FIG. 11). As depicted in FIG. 12, the processor computes the estimation value Δθ_{c_H} of the phase deviation (phase deviation Δθ) by performing proportional control and integral control such that the power deviation (deviation ΔP_{c}) between the reactive powers is zero in the medium/high speed range where the frequency command value ωᵣ* is equal to or larger than a threshold value.

Accordingly, stable and highly-accurate control of the magnet motor 1 can be realized in all the speed ranges.

### Fourth Embodiment

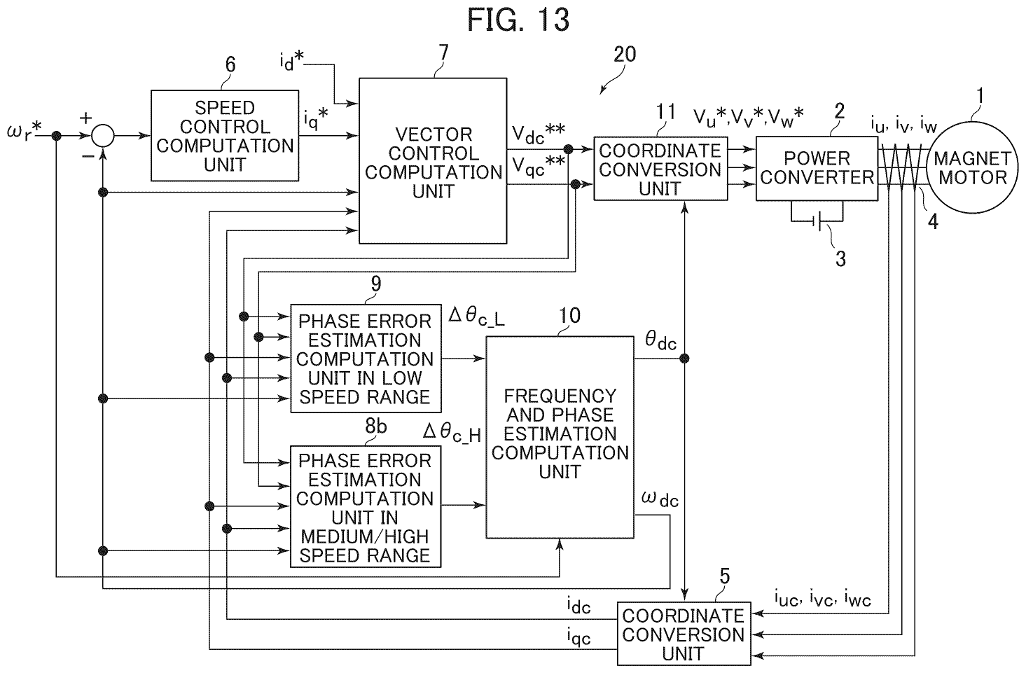

FIG. 13 is a configuration diagram of a power conversion device according to an embodiment.

In the third embodiment, the first active power P_{c} is computed from the voltage command values v_{dc}** and v_{qc}** and the current detection values i_{dc} and i_{qc} of the d_{c} axis and the q_{c} axis, but in the fourth embodiment, the first active power P_{c} is computed by using the amplitude value V₁* of the voltage command of the three-phase AC, the amplitude value i₁ of the current detection value, and a cosine signal of the phase θᵥ₁.

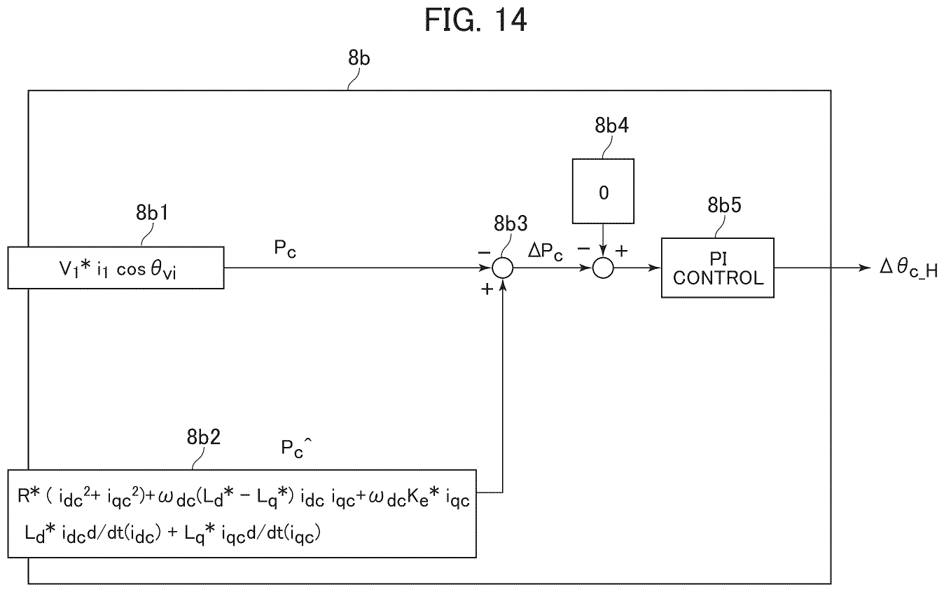

FIG. 14 is a phase error estimation computation unit 8b in the medium/high speed range of an embodiment of the present invention. The reference numeral 8b of the drawing corresponds to the reference numeral 8 in FIG. 2. The reference numerals 1 to 7 and 9 to 11 in the drawing are the same as those in FIG. 1.

The reference numerals 8b2, 8b3, 8b4, and 8b5 in FIG. 14 are the same as the reference numerals 8a2, 8a3, 8a4, and 8a5 in FIG. 12, respectively. In FIG. 14, in 8b1, the amplitude value V₁* of the voltage command of the three-phase AC is obtained in accordance with Equation (12) described above, the amplitude value i₁ of the current detection value is obtained in accordance with Equation (13) described above, the phase θᵥ₁ is obtained in accordance with Equation (14) described above, and the active power P_{c} is computed by using Equation (19).

$$\begin{matrix}[ Equation 19 ] & \\ {P}_{c} = {v}_{1}^{*} {i}_{1} cos [ {θ}_{vi} ] & ( 19 )\end{matrix}$$

Even if the present embodiment is used, highly-accurate control characteristics can be realized as similar to the first embodiment.

The main features of the fourth embodiment can also be summarized as follows.

As depicted in FIG. 14, the processor of the power conversion device 20 computes the first power (first active power P_{c}) from the product of the voltage amplitude value (amplitude value V₁* of the voltage command) of one phase of the three-phase AC, the current amplitude value (amplitude value i₁ of the current detection value) of the phase, and the cosine signal cos[θᵥ₁] of the phase difference between the voltage command value and the current detection value of the phase (Equation (19)). The processor computes the second power (second active power P_{c}\hat{ }) from the electrical circuit parameters (R*, L_{d}*, L_{q}*, and Kₑ*), the steady components (current detection values i_{dc} and i_{qc}) and the transient components dt/d(i_{dc}) and dt/d(i_{qc}) of the current detection values or the current command values of the d axis and the q axis, and the frequency estimation value ω_{dc}. Stable and highly-accurate control of the magnet motor 1 can be realized on the basis of the cosine signal of the three-phase AC.

### Fifth Embodiment

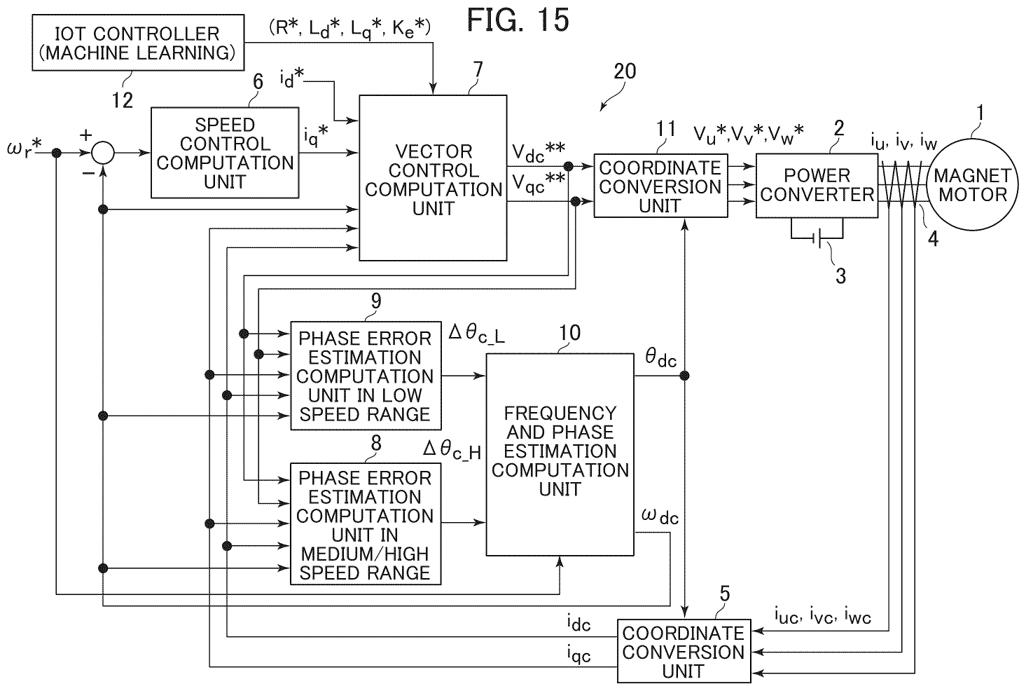

FIG. 15 is a configuration diagram of a power conversion device according to an embodiment.

The first to fourth embodiments are configured to set the electric circuit parameters of the magnet motor 1 in the controller (microcomputer or the like) of the power converter 2, but in the present embodiment, the state amount of control is fed back to a higher IoT controller, and then the machine-learned electric circuit parameters are re-set in the controller of the power converter.

The reference numeral 1 to 11 in the drawing are the same as those in FIG. 1. The reference numeral 12 denotes an IoT controller that executes machine learning.

In the present embodiment, the voltage command values v_{dc}** and v_{qc}**, the current detection values i_{dc} and i_{qc}, and the estimation value Δθ_{c} of the phase error are fed back to the higher IoT controller 12, and then the machine-learned electric circuit parameters (R*, L_{d}*, L_{q}*, and Kₑ*) are re-set in the controller of the power converter 2.

Even if the present embodiment is used, more stable and highly-accurate control characteristics can be realized as similar to the first embodiment.

The main features of the fifth embodiment can also be summarized as follows.

The processor of the power conversion device 20 transmits the voltage command values v_{dc}** and v_{qc}**, the current detection values i_{dc} and i_{qc}, and the estimation value Δθ_{c} of the phase deviation to the controller (IoT controller) of the higher device via a communication device.

The controller of the higher device analyzes (machine learning) the values received from the power conversion device 20 and transmits the analysis result to the power conversion device 20.

As depicted in FIG. 15, the processor of the power conversion device 20 receives the inductances L_{d}* and L_{q}* of the d axis and the q axis or the induced voltage coefficient Kₑ* of the magnet motor analyzed (machine learning) on the basis of the voltage command values v_{dc}** and v_{qc}**, the current detection values i_{dc} and i_{qc}, and the estimation value Δθ_{c} of the phase deviation from the controller (IoT controller) of the higher device via the communication device. The processor of the power conversion device 20 updates the electrical circuit parameters stored in a storage device of the power conversion device 20, with the received values. Accordingly, the electric circuit parameters can be automatically updated.

### Sixth Embodiment

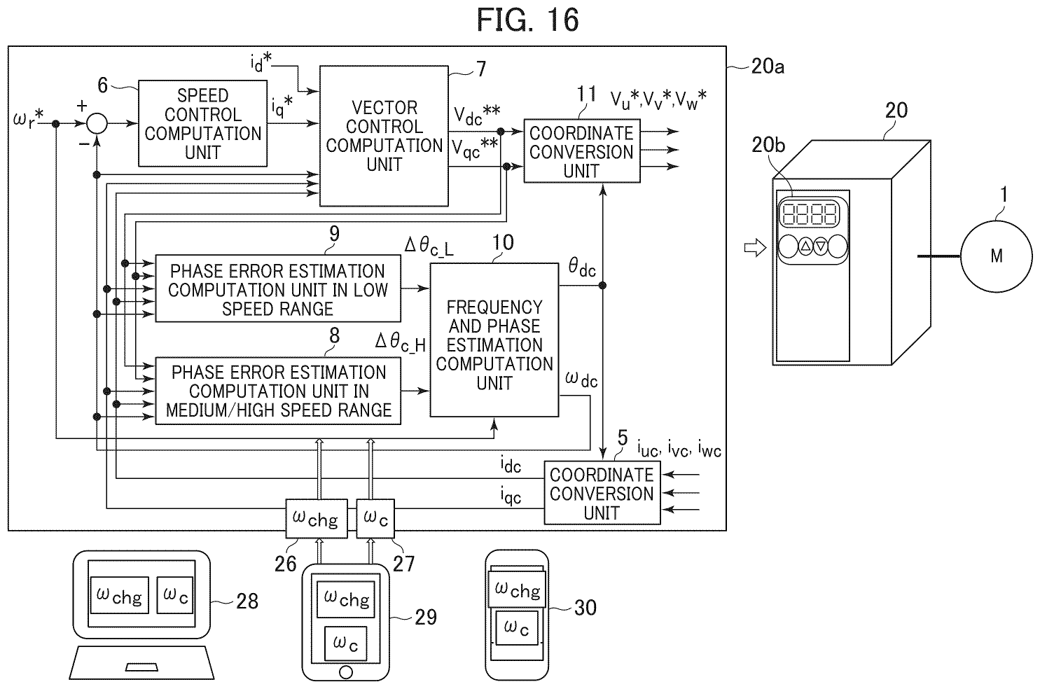

FIG. 16 is a configuration diagram of a power converter according to an embodiment. The present embodiment is an embodiment in which the first embodiment is applied to a magnet motor drive system. In the drawing, the constitutional elements of the reference numerals 1 and 5 to 11 are the same as those in FIG. 1.

The magnet motor 1 as a constitutional element of FIG. 1 is driven by the power conversion device 20. In the power conversion device 20, the constitutional elements of the reference numerals 5 to 11 in FIG. 1 are mounted as software 20a, and the constitutional elements of the reference numerals 2, 3, and 4 in FIG. 1 are mounted as hardware. In addition, “ω_{chg} that is the switching frequency 26 between the low speed range and the medium/high speed range,” and “ω_{c} that is the control response 27 of the phase error in the low speed range” of the software 20a can be set and changed by a higher device such as a digital operator 20b, a personal computer 28, a tablet 29, or a smartphone 30.

If the present embodiment is applied to the magnet motor drive system, highly-accurate control characteristics can be realized in the position sensorless vector control. In addition, “ω_{chg} that is the switching frequency 26 between the low speed range and the medium/high speed range,” and “ω_{c} that is the control response 27 of the phase error in the low speed range” may be set on a field bus of a programmable logic controller, a local area network connected to a computer, an IoT controller, or the like.

Further, although the present embodiment is disclosed by using the first embodiment, the second to fifth embodiments may be used.

The main features of the sixth embodiment can also be summarized as follows.

The power conversion device 20 depicted in FIG. 16 includes a storage device (for example, a non-volatile memory) for storing the threshold value (switching frequency 26, ω_{chg}) and the control response 27 (ω_{c} or the like) used for proportional control or integral control. The power conversion device 20 includes a communication device for communicating with an input device (digital operator 20b or the like) for setting the threshold value (switching frequency 26, ω_{chg}) and the control response 27 (ω_{c} or the like), or the external devices (the personal computer 28, the tablet 29, the smartphone 30, and the like) that set the threshold value and the control response.

Accordingly, the user can easily set the threshold value (switching frequency 26, ω_{chg}) and the control response 27 (ω_{c} or the like).

In the first to fifth embodiments, the current detection values i_{dc} and i_{qc} are used in Equation (6) as the first reactive power Q_{c} and Equation (7) as the second reactive power Q_{c}\hat{ }, but the current command values i_{d}* and i_{q}* may be used. In addition, the current detection values i_{dc} and i_{qc} are used in Equation (16) as the first active power P_{c} and Equation (17) as the second reactive power P_{c}\hat{ }, but the current command values i_{d}* and i_{q}* may be used.

Further, in the first to fifth embodiments, the voltage correction values Δv_{dc} and Δv_{qc} are created from the current command values i_{d}* and i_{q}* and the current detection values i_{dc} and i_{qc}, and the computation depicted in Equation (4) for adding the voltage correction values and the voltage reference value of the vector control is performed, but the intermediate current command values i_{d}** and i_{q}** depicted in Equation (20) used for the vector control computation are created from the current command values i_{d}* and i_{q}* and the current detection values i_{dc} and i_{qc}, and the vector control computation depicted in Equation (21) may be performed by using the frequency estimation value ω_{dc} and the electric circuit parameters of the magnet motor 1.

$$\begin{matrix}[ Equation 20 ] & \\ [ \begin{matrix}{i}_{d}^{**} = ( {K}_{pd 1} + \frac{{K}_{id 1}}{s} ) ( {i}_{d}^{*} - {i}_{d c} ) \\ {i}_{q}^{**} = ( {K}_{pq 1} + \frac{{K}_{iq 1}}{s} ) ( {i}_{q}^{*} - {i}_{q c} )\end{matrix} ] & ( 20 )\end{matrix}$$

$$\begin{matrix}[ Equation 21 ] & \\ [ \begin{matrix}{v}_{d c}^{** *} = {R}^{*} {i}_{d}^{**} - {ω}_{r}^{\hat{}} {L}_{q}^{*} \frac{1}{1 + {T}_{q} s} {i}_{q}^{**} \\ {v}_{d c}^{** *} = {R}^{*} {i}_{d}^{**} + {ω}_{r}^{\hat{}} {L}_{q}^{*} \frac{1}{1 + {T}_{q} s} {i}_{q}^{**} + {ω}_{r}^{\hat{}} {K}_{e}^{**}\end{matrix} ] & ( 21 )\end{matrix}$$

Here, K_{pd1} is a proportional gain of current control of the d_{c} axis, K_{id1} is an integral gain of current control of the d_{c} axis, K_{pq1} is a proportional gain of current control of the q_{c} axis, K_{ig1} is an integral gain of current control of the q_{c} axis, T_{d} is an electric time constant (L_{d}/R) of the d axis, and T_{q} is an electric time constant (L_{q}/R) of the q axis.

Alternatively, from the current command values i_{d}* and i_{q}* and the current detection values i_{dc} and i_{qc}, a voltage correction value Δv_{d_p}* of the proportional computation component of the d_{c} axis used for the vector control computation, a voltage correction value Δ_{vd_i}* of the integral computation component of the d_{c} axis, a voltage correction value Δ_{cq_p}* of the proportional computation component of the q_{c} axis, and a voltage correction value Δ_{vq_i}* of the integral computation component of the q_{c} axis are created by Equation (22), and the vector control computation depicted in Equation (23) using the frequency value estimation ω_{dc} and the electric circuit parameters of the magnet motor 1 may be performed.

$$\begin{matrix}[ Equation 22 ] & \\ [ \begin{matrix}Δ {v}_{d \_ p}^{*} = {K}_{pd 2} ( {i}_{d}^{*} - {i}_{d c} ) \\ Δ {v}_{d \_ i}^{*} = \frac{{K}_{id 2}}{s} ( {i}_{d}^{*} - {i}_{d c} ) \\ Δ {v}_{q \_ p}^{*} = {K}_{pd 2} ( {i}_{q}^{*} - {i}_{q c} ) \\ Δ {v}_{q \_ i}^{*} = \frac{{K}_{iq 2}}{s} ( {i}_{q}^{*} - {i}_{qc}\end{matrix} ] & ( 22 )\end{matrix}$$

$$\begin{matrix}[ Equation 23 ] & \\ [ \begin{matrix}{v}_{d c}^{** **} = ( Δ {v}_{d \_ p}^{*} + Δ {v}_{d \_ i}^{*} ) - {ω}_{r}^{\hat{}} \frac{{L}_{q}^{*}}{{R}^{*}} Δ {v}_{q \_ i}^{*} \\ {v}_{qc}^{** **} = ( Δ {v}_{q \_ p}^{*} + Δ {v}_{q \_ i}^{*} ) - {ω}_{r}^{\hat{}} \frac{{L}_{d}^{*}}{{R}^{*}} Δ {v}_{d \_ i}^{*} + {ω}_{r}^{\hat{}} {K}_{e}^{*}\end{matrix} ] & ( 23 )\end{matrix}$$

Here, the vector control computation depicted in Equation (24) may be performed by using K_{pd2} as a proportional gain of the current control of the d_{c} axis, K_{id2} as an integral gain of the current control of the d_{c} axis, K_{pq2} as a proportional gain of the current control of the q_{c} axis, K_{iq2} as an integral gain of the current control of the q_{c} axis, a primary delay signal i_{qctd} of the current command value i_{d}* of the d_{c} axis and the current detection value i_{gc} of the q_{c} axis, the frequency estimation value ω_{dc}, and the electric circuit parameters of the magnet motor 1.

$$\begin{matrix}[ Equation 24 ] & \\ [ \begin{matrix}{v}_{d c}^{** ** *} = {R}^{*} {i}_{d}^{*} - {ω}_{r}^{\hat{}} {L}_{q}^{*} {i}_{qctd} \\ {v}_{q c}^{** ** *} = {R}^{*} {i}_{qctd} - {ω}_{r}^{\hat{}} {L}_{d}^{*} {i}_{d}^{*} + {ω}_{r}^{\hat{}} {K}_{e}^{**}\end{matrix} ] & ( 24 )\end{matrix}$$

It should be noted that in the first to sixth embodiments, the switching element configuring the power converter 2 may be a silicon (Si) semiconductor element or a wide bandgap semiconductor element such as silicon carbide (SiC) or gallium nitride (GaN).

The above embodiments are examples for explaining the present invention and have been omitted and simplified as appropriate in order to clarify the explanation. The present invention can be carried out in various other forms. Unless otherwise specified, each constitutional element may be singular or multiple. The position, size, shape, range, and the like of each constitutional element depicted in the drawings do not represent the actual position, size, shape, range, and the like in some cases in order to facilitate understanding of the invention. Therefore, the present invention is not necessarily limited to the positions, sizes, shapes, ranges, and the like disclosed in the drawings. Examples of the various types of information are described by expressions such as “table,” “list,” and “queue,” but the various types of information may be expressed by data structures other than these. For example, various types of information such as “XX table,” “XX list,” and “XX queue” may be “XX information.” When explaining identification information, expressions such as “identification information,” “identifier,” “name,” “ID,” and “number” are used, but they can be replaced with each other. In the case where there are multiple constitutional elements having the same or similar functions, they are described by adding different subscripts to the same reference numerals in some cases. In addition, in the case where it is not necessary to distinguish these constitutional elements from each other, they are described by omitting the subscripts in some cases. In the embodiments, a process performed by executing a program is described in some cases. Here, a computer executes a program by a processor (for example, a CPU or a GPU), and performs a process specified by the program while using a storage resource (for example, a memory), an interface device (for example, a communication port), or the like. Therefore, the main body of the process performed by executing the program may be the processor. Similarly, the main body of the process performed by executing the program may be a controller, a device, a system, a computer, or a node having a processor. The main body of the process performed by executing the program may be a computation unit, and may include a dedicated circuit for performing a specific process. Here, the dedicated circuit is a field programmable gate array (FPGA), an application specific integrated circuit (ASIC), a complex programmable logic device (CPLD), or the like. The program may be installed on a computer from a program source. The program source may be, for example, a program distribution server or a computer readable storage medium. In the case where the program source is a program distribution server, the program distribution server includes a processor and a storage resource for storing a program to be distributed, and the processor of the program distribution server may distribute the program to be distributed to other computers. In addition, in the embodiments, two or more programs may be realized as one program, or one program may be realized as two or more programs.

The present invention is not limited to the above embodiments, but includes various modified examples. For example, the above-described embodiments have been described in detail for the purpose of clearly explaining the present invention, and are not necessarily limited to those having all of the described configurations. In addition, it is possible to replace a part of a configuration of one embodiment with a configuration of another embodiment, and to add a configuration of an embodiment to a configuration of another embodiment. In addition, for a part of a configuration of each embodiment, addition, deletion, or replacement of another configuration is possible.

It should be noted that the embodiments of the present invention may have the following modes.

(C1). In a power conversion device for controlling the output frequency, the output voltage, and the output current of a magnet motor, the deviation between the phase of control and the phase of the magnetic flux of the motor is estimated such that a first power computed from the output voltage and the output current of the magnet motor follows a second power computed from electric circuit parameters of the magnet motor, steady components and transient components of the output current, and a frequency estimation value, and the frequency estimation value is controlled by using the estimation value of the relevant phase deviation.

(C2). In a power conversion device for controlling the output frequency, the output voltage, and the output current of a magnet motor, the deviation between the phase of control and the phase of the magnetic flux of the motor is estimated such that a first reactive power computed from the output voltage and the output current of the magnet motor follows a second reactive power computed from electric circuit parameters of the magnet motor, steady components and transient components of the output current, and a frequency estimation value, and the frequency estimation value is controlled by using the estimation value of the relevant phase deviation.

(C3). In a power conversion device for controlling the output frequency, the output voltage, and the output current of a magnet motor, the deviation between the phase of control and the phase of the magnetic flux of the motor is estimated such that a first active power computed from the output voltage and the output current of the magnet motor follows a second active power computed from electric circuit parameters of the magnet motor, steady components and transient components of the output current, and a frequency estimation value, and the frequency estimation value is controlled by using the estimation value of the relevant phase deviation.

(C4). In a power conversion device of vector control that computes voltage command values of the d axis and the q axis by using current command values and current detection values of the d axis as the magnetic flux axis of a magnet motor and the q axis as the torque axis, and a frequency estimation value, the deviation between the phase of control and the phase of the magnetic flux of the motor is estimated such that a first reactive power obtained by multiplying the voltage command values and the current detection values of different components of the d axis and the q axis and adding them (expressed as adding in consideration of the positive and negative of the values) follows a second reactive power computed from electric circuit parameters of the magnet motor, steady components and transient components of the current detection values or the current command values of the d axis and the q axis, and a frequency estimation value, and the frequency estimation value is controlled by using the estimation value of the relevant phase deviation.

(C5). In a power conversion device of vector control that computes voltage command values of three-phase AC by using current command values and current detection values of the three-phase AC of a magnet motor and a frequency estimation value, the deviation between the phase of control and the phase of the magnetic flux of the motor is estimated such that a first reactive power obtained by multiplying a voltage amplitude value and a current amplitude value of one phase of the three-phase AC and a sine signal of the phase difference between the voltage command value and the current detection value follows a second reactive power computed from electric circuit parameters of the magnet motor, steady components and transient components of the current detection values or the current command values of the d axis and the q axis, and the frequency estimation value, and the frequency estimation value is controlled by using the estimation value of the relevant phase deviation.

(C6). In a power conversion device of vector control that computes voltage command values of the d axis and the q axis by using current command values and current detection values of the d axis as the magnetic flux axis of a magnet motor and the q axis as the torque axis, and a frequency estimation value, the deviation between the phase of control and the phase of the magnetic flux of the motor is estimated such that a first active power obtained by multiplying the voltage command values and the current detection values of the same component of the d axis and the q axis and adding them follows a second active power computed from electric circuit parameters of the magnet motor, steady components and transient components of the current detection values or the current command values of the d axis and the q axis, and the frequency estimation value, and the frequency estimation value is controlled by using the estimation value of the relevant phase deviation.

(C7). In a power conversion device of vector control that computes voltage command values of three-phase AC by using current command values and current detection values of the three-phase AC of a magnet motor and a frequency estimation value, a phase error (phase deviation) that is the deviation between the phase of control and the phase of the magnetic flux of the motor is estimated such that a first active power obtained by multiplying a voltage amplitude value and a current amplitude value of one phase of the three-phase AC and a cosine signal of the phase difference between the voltage command value and the current detection value follows a second active power computed from electric circuit parameters of the magnet motor, steady components and transient components of the current detection values or the current command values of the d axis and the q axis, and the frequency estimation value, and the frequency estimation value is controlled such that the estimation value of the relevant phase error follows the command value thereof.

(C8). In the power conversion device according to any one of (C1) to (C7), the estimation computation of the phase error that is the deviation between the phase of control and the phase of the magnetic flux of the motor is performed by proportional control and integral control performed such that the deviation between the first and second reactive powers or the deviation between the first and second reactive powers is zero.

(C9). In the power conversion device according to (C8), on the basis of the relationship between the electric circuit parameters of the magnet motor and the frequency estimation value, the estimation computation of the phase error is performed by proportional control and integral control performed such that the deviation between the first and second reactive power information is zero if the magnet motor is in the low speed range and the deviation between the first and second active power information is zero if the magnet motor is in the medium/high speed range.

(C10). In the power conversion device according to (C8), on the basis of the relationship between the electric circuit parameters of the magnet motor and the frequency estimation value, proportional control and integral control performed so as to make the deviation between the first and second reactive power information is zero if the magnet motor is in the low speed range, and the phase error is computed directly by an extended induced voltage method if the magnet motor is in the medium/high speed range.

(C11). In the power conversion device according to (C9) and (C10), a frequency value for switching control between the low speed range and the medium/high speed range, and a control response set in proportional control or integral control for estimating the phase error are set in a microcomputer internal memory or the like mounted in the power conversion device including a power converter, and can be freely set and changed by connecting thereto a digital operator, a personal computer, a tablet, or a smartphone device.

(C12). In the power conversion device according to (C11), the voltage command values, the current detection values, and the estimation value of the phase error are fed back to an IoT controller as a higher device for analysis, and the d-axis and q-axis inductances and the induced voltage coefficient of the magnet motor are automatically corrected.

According to (C1) to (C12), the phase error is estimated by using the reactive power computed using the steady components and the transient components of the current detection values, and the output frequency of the magnet motor is estimated by using the relevant phase error, so that a torque shock when switching from the low speed range to the medium/high speed range can be prevented, and it is possible to provide a power converter that realizes highly-accurate control characteristics without adjusting the electric circuit parameters and the control gains of the magnet motor set in a controller.

### DESCRIPTION OF REFERENCE CHARACTERS

1: Magnet motor
2: Power converter
3: DC power supply
4: Current detector
5: Coordinate conversion unit
6: Speed control computation unit
7: Vector control computation unit
8, 8a, 8b: Phase error estimation computation unit in medium/high speed range
9, 9a, 9b: Phase error estimation computation unit in low speed range
10: Frequency and phase estimation computation unit
11: Coordinate conversion unit
12: IoT controller
20: Power conversion device
20a: Software (software part) of power conversion device
20b: Digital operator of power conversion device
21: Voltage detector
22: Current detector
23: Encoder
24: Calculation unit for voltage/current of vector component
25: Observation unit for waveforms at various points
26: Set value of switching frequency between low speed range and medium/high speed range
27: Set value of control response in low speed range
28: Personal computer
29: Tablet
30: Smartphone
i_{d}*: Current command value of d axis
i_{q}*: Current command value of q axis
i_{dc}: Current detection value (steady component) of d axis
i_{dc}: Current detection value (steady component) of q axis
d/dt(i_{dc}): Transient component of current detection value of
d axis
d/dt(i_{qc}): Transient component of current detection value of q axis
ω_{dc}: Frequency estimation value
ωr: Speed of magnet motor 1
v_{dc}*, v_{dc}**, v_{dc}**, v_{dc}***, v_{dc}****, v_{dc}*****: Voltage command value of d axis
v_{qc}*, v_{qc}**, v_{qc}***, v_{qc}****, v_{qc}*****: Voltage command value of q axis
Q_{c}: First reactive power
Q_{c}\hat{ }: Second reactive power
P_{c}: First active power
P_{c}\hat{ }: Second active power
Aθ_{c_L}: Estimation value of phase error in low speed range
Δθ_{c_H: Estimation value of phase error in medium/high speed range}
Δθ_{c}: Estimation value of phase error

What is claimed is:

1. A power conversion device comprising: a processor that computes a first power from a voltage and a current of a magnet motor, computes a second power from electric circuit parameters of the magnet motor, steady components and transient components of the current of the magnet motor, and a frequency estimation value of the magnet motor, estimates a phase deviation indicating a deviation between a phase of control and a phase of a magnetic flux of the magnet motor such that the first power follows the second power, and computes the frequency estimation value from an estimation value of the phase deviation.

2. The power conversion device according to claim 1,
wherein the first power and the second power are reactive powers.

3. The power conversion device according to claim 1,
wherein the first power and the second power are active powers.

4. The power conversion device according to claim 2,
wherein the processor
computes the first power from a difference between products of voltage command values and current detection values of different components of a d axis as a magnetic flux axis of the magnet motor and a q axis as a torque axis of the magnet motor, and
computes the second power from the electric circuit parameters, steady components and transient components of current detection values or current command values of the d axis and the q axis, and the frequency estimation value.

5. The power conversion device according to claim 2,
wherein the processor
computes the first power from a product of a voltage amplitude value of one phase of three-phase AC, a current amplitude value of the phase, and a sine signal of a phase difference between a voltage command value and a current detection value of the phase, and
computes the second power from the electric circuit parameters, steady components and transient components of current detection values or current command values of a d axis and a q axis, and the frequency estimation value.

6. The power conversion device according to claim 3,
wherein the processor
computes the first power from a sum of products of voltage command values and current detection values of a same component of a d axis as a magnetic flux axis of the magnet motor and a q axis as a torque axis of the magnet motor, and
computes the second power from the electric circuit parameters, steady components and transient components of current detection values or current command values of the d axis and the q axis, and the frequency estimation value.

7. The power conversion device according to claim 3,
wherein the processor
computes the first power from a product of a voltage amplitude value of one phase of three-phase AC, a current amplitude value of the phase, and a cosine signal of a phase difference between a voltage command value and a current detection value of the phase, and
computes the second power from the electric circuit parameters, steady components and transient components of current detection values or current command values of a d axis and a q axis, and the frequency estimation value.

8. The power conversion device according to claim 1,
wherein the processor
computes the estimation value of the phase deviation by performing proportional control and integral control such that a power deviation indicating a deviation between the first power and the second power is zero.

9. The power conversion device according to claim 8,
wherein the processor
computes the estimation value of the phase deviation by performing the proportional control and the integral control such that the power deviation between reactive powers is zero in a low speed range where a frequency command value is less than a threshold value, and
computes the estimation value of the phase deviation by performing the proportional control and the integral control such that the power deviation between active powers is zero in a medium/high speed range where the frequency command value is equal to or larger than the threshold value.

10. The power conversion device according to claim 8,
wherein the processor
computes the estimation value of the phase deviation by performing the proportional control and the integral control such that the power deviation between reactive powers is zero in a low speed range where a frequency command value is less than a threshold value, and
computes the estimation value of the phase deviation by an extended induced voltage method in a medium/high speed range where the frequency command value is equal to or larger than the threshold value.

11. The power conversion device according to claim 9, the device comprising:
a storage device that stores the threshold value and a control response used for the proportional control or the integral control;
an input device that sets the threshold value and the control response; or
a communication device that communicates with an external device for setting the threshold value and the control response.

12. The power conversion device according to claim 11,
wherein the processor
transmits voltage command values, current detection values, and an estimation value of the phase deviation to a controller of a higher device via the communication device,
receives inductances of a d axis and a q axis of the magnet motor or an induced voltage coefficient, the inductances and the induced voltage coefficient being analyzed on a basis of the voltage command values, the current detection values, and the estimation value of the phase deviation, from the controller of the higher device via the communication device, and
updates the electric circuit parameters with the received values.

13. The power conversion device according to claim 1,
wherein the processor
computes the second power from the electrical circuit parameters, steady components and transient components of current detection values or current command values of a d axis and a q axis, and the frequency estimation value.
